(19) United States
(12) Patent Application Publication
(10) Pub. No.: US 2005/0227049 A1
(43) Pub. Date: Oct. 13, 2005

(54) Process for fabrication of printed circuit boards

(76) Inventors: James R. Boyack, Bedford, NH (US); Peter H. Roth, Bedford, NH (US); N. Edward Berg, Bedford, NH (US)

Correspondence Address: HAYES, SOLOWAY P.C., 130 W. CUSHING STREET, TUCSON, AZ, 85701, US

(21) Appl. No.: 11/085,498

(22) Filed: Mar. 21, 2005

Related U.S. Application Data
(60) Provisional application No. 60/555,274, filed on Mar. 22, 2004.
(60) Provisional application No. 60/556,761, filed on Mar. 26, 2004.

(51) Int. Cl. G03F 9/00; B05D 3/02

(52) U.S. Cl. 428/195.1; 428/901; 427/372.2

(57) ABSTRACT

A method of making a printed circuit board by coating a surface of a substrate with an electrically conductive polymer and curing or setting the polymer on the substrate. The polymer coating is laced with a catalytic reducing agent.

### CROSS-REFERENCE TO RELATED APPLICATION

This application claims priority to copending U.S. provisional application entitled, “A Direct Process for Fabrication of PCBs” having Ser. No. 60/555,274, filed Mar. 22, 2004, which is entirely incorporated herein by reference and copending U.S. provisional application entitled, “A Direct Process for Fabrication of Electronic Interconnections PCBs” having Ser. No. 60/556,761, filed Mar. 26, 2004, which is entirely incorporated herein by reference.

### TECHNICAL FIELD

The present invention relates to a process and apparatus for forming single-sided, double-sided, or multi-layer circuit boards.

### BACKGROUND OF THE INVENTION

The fabrication of printed circuit boards (PCBs) remains a core technology in the manufacture and assembly of electronic devices. Current methods are complex, costly and use many toxic and environmentally undesirable chemicals.

The manufacture of printed circuit boards generally follows either subtractive or additive processing techniques. According to a general subtractive process for the manufacture of printed circuit boards, a conductive layer laminated to a non-conductive substrate is selectively removed to leave a desired pattern of conductive pathways. The pattern of conductive pathways is typically formed by providing the conductive layer with a resist film, for example, containing photosensitive organic monomers. Upon exposure to ultraviolet light, the photosensitive organic monomers polymerize, forming hardened regions. Two types of resists are in common usage today: dry film resists, containing a thin film of photosensitive monomers covered by a ultraviolet-transparent protective film, and liquid resists, also containing photosensitive organic monomers, often present in a solution allowing application as a liquid.

Once the resist has been applied to the conductive layer, the resist is photo-imaged, i.e., selectively exposed to an appropriate ultraviolet light source. An imaging mask is interposed between the source of ultraviolet light and the circuit board containing the resist. The imaging mask includes an ultraviolet-opaque member having an ultraviolet-transparent pattern therein. Accordingly, when the circuit board is photo-imaged only those regions corresponding to the ultraviolet-transparent pattern will be exposed and polymerized.

Subsequent to imaging, the unexposed, and therefore un-polymerized regions of the resist are removed, as through the use of appropriate solvents. The regions of the conductive layer not protected by the polymerized resist are then removed using an acid or alkaline solution. Once the resist has been removed, the non-conductive substrate is left having a conductive layer formed in a pattern corresponding to ultraviolet-transparent pattern of the imaging mask.

Additive processes for the manufacture of printed circuit boards typically begin with a non-conductive substrate upon which conductive pathways are selectively added. Consistent with a conventional additive process, a non-conductive substrate is coated with a resist layer, such as those employed during subtractive methods. The substrate bearing the resist layer is imaged with a negative photo-resist, wherein only those regions corresponding to the desired pattern of conductive pathways remains unexposed. Accordingly, when the resist is developed, i.e., the un-polymerized resist is removed, and the non-conductive substrate is exposed in the regions corresponding to the desired conductive pathways. Plating the exposed portions of the non-conductive substrate with a conductive material, and then removing the polymerized regions of the resist completes the process.

It is often desirable to connect electronic elements on one surface to elements on another surface of the substrate. Often this is done by means of through holes or passageways that penetrate the substrate, and run from one surface of the substrate to the other surface. These passageways may be made conductive by elements in the passageways that provide connections between electronic and/or conductive elements on surfaces of the substrate. The passageways may be made by mechanical means, e.g. drilling or punching, chemical means, e.g. etching, light means, e.g. laser drilling or other hole forming means. A multiplicity of conductors may run through a passageway.

These passageways or holes through surfaces of a substrate having, within them, conductive elements are often used in the fabrication of PCBs. The holes may have conductive elements to connect elements on surfaces of a single substrate thereby forming what may be referred to as a two-sided PCB. Two or more substrates stacked upon each other may be used in forming multi-layer PCBs. The walls of these passageways often need to be made conductive to function as substrate layer-to-substrate layer connections. Multiple connection elements may exist in the holes or passageways.

Current practice in the preparation of passageways, prior to making them conductive may involve cleaning and removal of plastic and fibrous debris, by the use of solvents or etching chemicals, which may include caustic fluids. Debris removal may be followed by the application of a coating of catalytic nuclei to the passageway. This catalytic nuclei seeding may provide the proper foundation for electro-less plating. Electro-plating often follows electro-less plating. Recently, alkaline and/or aqueous dispersions of conductive colloids and/or graphite dispersions, and proprietary additives in binders and/or fixers are being used to make PCB substrate holes conductive enough for electroplating. These processes, electro-less copper and the above mentioned alternatives, all utilize relatively complex chemical processing often involving toxicants and large amounts of rinse water, and multiple process steps.

Some PCBs are made of a composite material called FR-4. This is an epoxy/fiberglass composite that is often plagued by residual fibers in the holes or passageways left after mechanical drilling, or by residual ash if laser drilled. For mechanically drilled holes the fibers created by the drilling process may be removed by chemical processing, before the passageway is made conductive. Thus, the finished PCB will have minimal functional, or mechanical or aesthetic defects. For laser drilled holes the ash created by material ablation may be removed by chemical means before the hole (passageway) is made conductive.

The above description of the prior art is taken largely from our copending U.S. application entitled, “Process and Apparatus for Manufacturing Printed Circuit Boards” Ser. No. 10/139,311, filed May 6, 2002, and U.S. application entitled “Method for Making Conductive Passageways and Surface Conductors in Electrical Structures” having Ser. No. 10/782,239, filed Feb. 19, 2004. Our '311 Application, teaches printing on the passageways in the non-conductive areas of a substrate and the surface connection an enhanced conductive polymer dispersion ink to eliminate the need for a variety of processing steps. Our '239 Application teaches direct printing methods using a laser print drum to apply a masking pattern to a substrate.

### SUMMARY OF THE INVENTION

This invention is a much simpler, quicker, less expensive, reduced chemical process for making PCBs and/or electronic interconnects. This direct process avoids the toxic chemical baths that are prevalent in the PCB industry.

Certain semi-conducting or conducting polymers films have the property of accepting small quantities of catalytic materials. Coating of these catalytic materials on the polymer films by themselves results in films that, generally, have low conductivity, poor chemical stability, and are not abrasion resistant, all of which make them unsuitable for many electronic circuits. The catalytic coating enables the polymer films to catalyze the reduction of many metals unto its surface. Applying electro-less plating to these catalytic coated polymer films for deposition of such metals as copper or nickel enhances the properties of the resultant surfaces. The resultant surfaces are hard, smooth, have good electrical conduction, and resistance to abrasion. The process may be used to make multi-layers of electronic interconnects with solder-mask and letter-screen .

This above method combined with suitable imaging methods can be used to create complex high-resolution circuits. Resolutions of feature sizes in the 1-2 Micron range can be obtained.

Other systems, methods, features, and advantages of the present invention will be or become apparent to one with skill in the art upon examination of the following drawings and detailed description. It is intended that all such additional systems, methods, features, and advantages be included within this description, be within the scope of the present invention, and be protected by the accompanying claims.

### BRIEF DESCRIPTION OF THE DRAWINGS

Many aspects of the invention can be better understood with reference to the following drawings. The components in the drawings are not necessarily to scale, emphasis instead being placed upon clearly illustrating the principles of the present invention. Moreover, in the drawings, like reference numerals designate corresponding parts throughout the several views.

FIG. 1 is a side view of one layer interconnection of a semiconductor device consistent with a first embodiment of the invention.

FIG. 2 is a side view of two layer interconnection of a semiconductor consistent with another embodiment of the invention.

FIG. 3 is side view of a two layer interconnection consistent with another embodiment of the invention.

FIG. 4 is a flowchart which illustrates a method of making a circuit board in accordance with an alternative embodiment of the invention.

### DETAILED DESCRIPTION

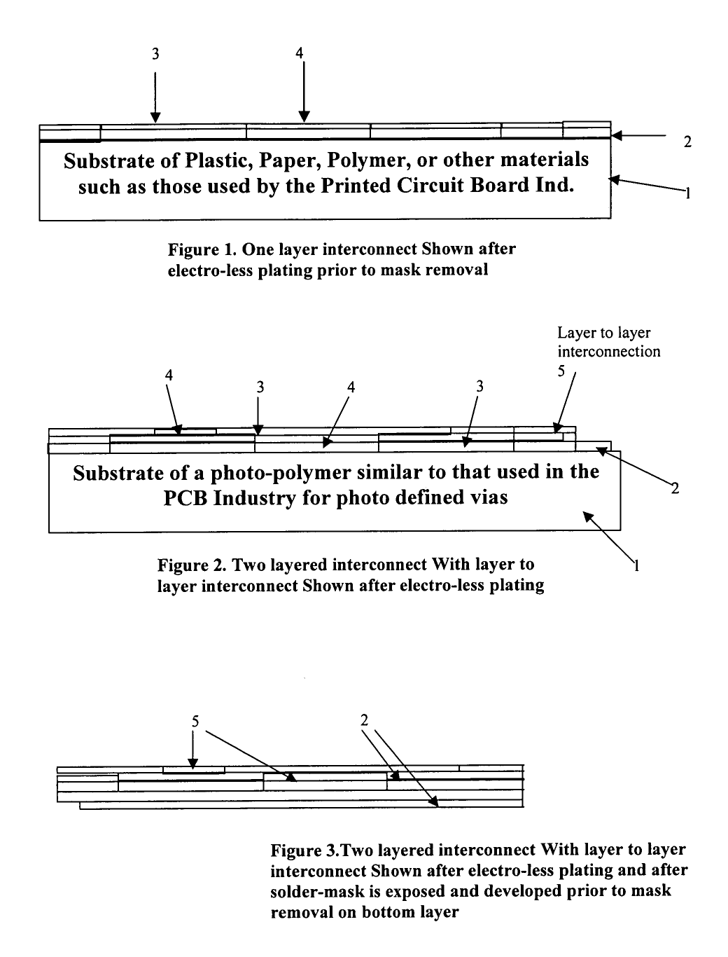

As shown in FIG. 1, the first embodiment of the fabrication process begins with the application, upon a substrate 1 such as paper, plastic etc., of a thin film of a suitable low conductivity polymer coating solution such as Baytron which is a commercially available low conductivity polymer which is available from Bayer Material Service, A.G., and is sold as an aqueous solution of poly (3, 4-ethylenedioxythiophene)-poly (styrenesulfonate) or “PEDT/PSS”, or any other suitable polymer, which is then laced with small quantities of a catalytic reducing agent. The preferred reducing agent is an aqueous dispersion of nano-particle palladium. Whatever reducing agent is used it should be compatible with the polymer coating. The combination of a suitable polymer with a compatible reducing agent dispersion 2 is coated or printed on to receptor substrate 1. The coating 2 allows for the forming of complex circuit patterns. To facilitate coating, wetting agents and suitable cross-linking agents and materials such as fine particle colloidal silver or other metals may be incorporated in the polymer coating solution 2; however, care must be taken not to allow the coating layer 2 to become too electrically conductive. If the coating 2 becomes too electrically conductive, it may interfere with the production quality, and functionality of the circuits.

After coating and drying, the resulting coating layer 2 can be cured to complete cross-linking or, another coating can be applied before completing the thermal curing process so that all the applied layers are simultaneously treated.

The next step in the process is the application of another masking layer 3. This masking layer 3 is used to create a negative image (mask) of the desired circuit. This masking layer 3 is added by applying a non-conducting toner using electro-photography or by direct printing with a non-conducting lithographic ink, lacquer or varnish. Alternatively, the masking layer 3 can also be applied utilizing an ink jet printer using a non-conducting polymer. If the polymer with the reducing agent is printed directly on the substrate in area 4 the area can be electro-less plated without the use of a mask.

After these coatings are dried and cured the entire coated substrate goes into an aqueous electroless-plating bath. The exposed catalyzed surface allows for the reduction and smooth deposition of a metal, and creating a highly conductive plated area 4. The masking layer 3 cannot be plated and thus acts as an insulating layer. By using this differential method, complex, electrically conducting circuits can be formed. The remaining, non-plated masking layer 3 may remain, since it is not conductive, or be removed as necessary for further processing. In this manner, many of the wet processing steps used in current fabrication, such as etching, electroplating, multiple washing steps and complex imaging steps are eliminated.

A second embodiment of this fabrication process involves formulating and applying an ink-jet composition directly to the receiving surface to create the coating layer 2, which is then electro-less plated, as previously described. This creates the circuit image directly, but is limited by the resolution and image quality of ink jet printing process.

In this second embodiment, the first step is coating the entire substrate with a polymer and the reducing agent. Next, a mask is printed lithographically or otherwise masked with a normal printing method. Finally, the masked substrate is electrolessly plated. Preferably the substrate is first plated with nickel, then with copper. Finally a second layer of nickel is applied, which creates a hard surface.

This process leaves printing ink in the circuit, which is normally a good thing. Ink is hard to remove and is very stable. Furthermore, by using a solvent based ink which contains both the polymer and the reducing agent, the ink can be used to print direct the circuit patterns and then electro-less plated.

A third embodiment involves using electro-photography and lithographic or offset printing to create the coating layer 2, which is then electro-less plated as previously described. This results in much higher resolution images and if pre-coated webs are made for the lithographic process, low cost, high speed, high volume repeat circuits can easily be manufactured. The use of electro-photography allows each image to be different and is ideal for prototype circuits where the desired quantity is low. Different masking patterns could be printed and used as required.

Subsequent steps in circuit manufacturing, such as application of a solder mask and protective coating can be accomplished by techniques well known in the art. The imaging of the photopolymer would be simplified by printing the mask, by electro-photographic printing or lithographic printing, directly on the photo polymer and thereby achieving higher resolutions than can be obtained on masks by screen-printing.

Multi-layered circuit interconnects (or circuit boards) with layer connecting vias can be created as composites of two sided structure with plated through holes as shown in FIG. 2 using another embodiment of the fabrication method. FIG. 2 shows a two layer interconnection with layer to layer interconnection after electro-less plating. As in the first embodiment, a substrate 1 is coated with a thin film of a suitable polymer coating solution 2 laced catalytic reducing agent. A masking layer 3 is then applied. Each layer of masked polymer is finally electro-less plated. This process then is repeated for each layer of the semiconductor device. Plating of the second layer includes printing conductive vias 5 (layer to layer connections) avoiding the need for making holes through substrates by mechanical, laser or other means, and the subsequent problem of making them conductive. Circuit elements and components can be attached to the direct printed circuits using highly conductive adhesives that can be cured at very low temperatures so as not to damage delicate electronic components. These adhesives are commercially available and in current use; they are sold by such companies as Devcon, Master Bond, Cummings and Henkel's Loctite Division.

Multiple layered structures can begin with applying a release layer to the starting substrate. After the desired layers of conductors are directly printed or alternately printed masked and electro-less plated, the interconnect structure can be released from the substrate. If holes through the printed multi-layer interconnect structure are desired they maybe made by electro-less plating on the appropriate conductive surface through the thin structure in already conductive areas avoiding the necessity of making the via holes conductive. Since the interconnect structure is thin the components may be pushed through the interconnect structure without the need for forming passageways through the structure.

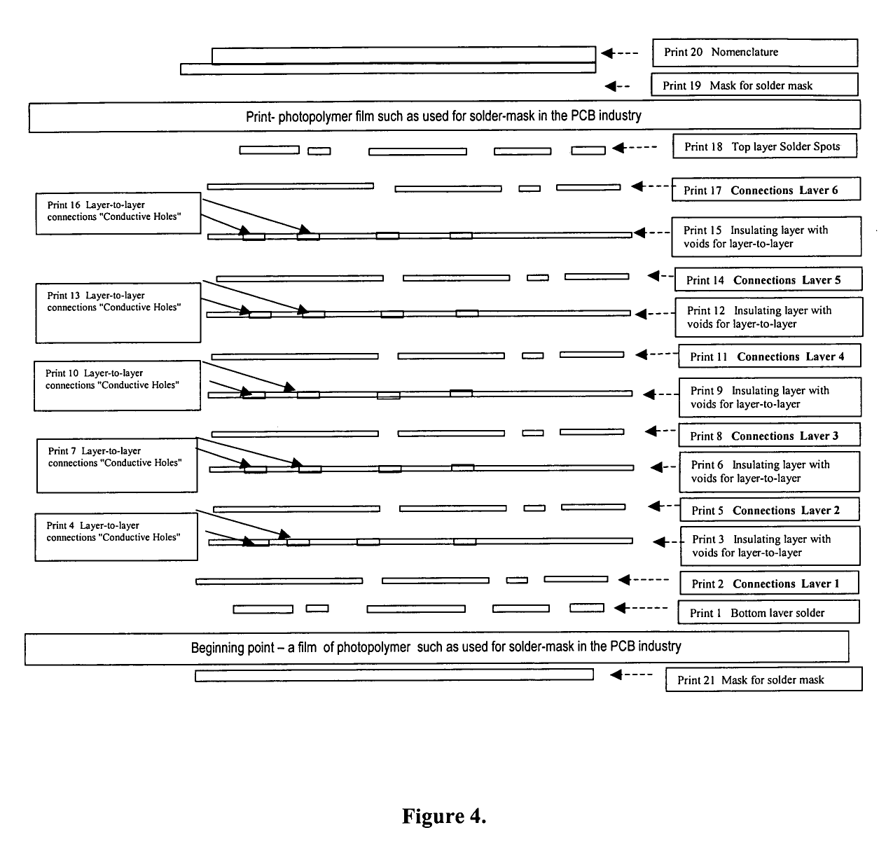

Solder mask can be made by building up the interconnect structure on a photopolymer film such as that used in the PCB industry for solder mask (see FIG. 4). The top most layers could consist of printing a photopolymer solder mask ink (film) which is then masked by techniques heretofore described and imaged and developed in the classical methods leaving a top layer solder mask. Printing upon the solder mask a heat or chemical setting polymer could provide a letter screen. The bottom layer could be solder masked by turning the structure over and processing the starting polymer film in the heretofore described method (see FIG. 4).

Photopolymers could be eliminated by the use of printing heat or chemical setting polymers in the required patterns and heat or chemically setting them.

Solder receptive areas on the interconnect structure could be established by electro-less plating a thick layer of a metal such as Ni which could be soldered to directly, in the desired areas, as an alternative to using conductive epoxy. Alternatively, the solder mask could be printed by a heat set polymer with appropriate properties. Printing highly conductive ink on the places where components are to be soldered and heat or chemically setting the ink would provide areas that components could be soldered to by spot heating.

It should be emphasized that the above-described embodiments of the present invention are merely possible examples of implementations, merely set forth for a clear understanding of the principles of the invention. Many variations and modifications may be made to the above-described embodiment(s) of the invention without departing substantially from the spirit and principles of the invention. All such modifications and variations are intended to be included herein within the scope of this disclosure and the present invention and protected by the following claims.

1. A method of making a printed circuit board comprising the steps of:
coating a surface of a substrate with a conductive polymer; and
curing or setting the polymer on said substrate,
wherein said polymer is laced with a catalytic reducing agent.

2. The method of claim 1, wherein said polymer comprises a poly (3, 4-ethylenedioxythiophene)-poly (styrenesulfonate).

3. The method of claim 1, wherein the catalytic reducing agent comprises a nano-particle metal.

4. The method of claim 3, wherein said nano-particle metal comprises palladium.

5. The method of claim 1, wherein said polymer also contains wetting agents and/or cross-linking agents.

6. The method of claim 1, wherein said polymer also contains fine particle colloidal silver or other metals.

7. The method of claim 1, further comprising the step of applying a masking layer to the coated surface of said substrate.

8. The method of claim 7, wherein said masking layer is applied using electro-photography with a non-conductive toner or by direct printing with a non-conducting lithographic ink, lacquer or varnish.

9. The method of claim 7, wherein said masking layer is applied by ink-jet printing directly on the coated surface of said substrate.

10. The method of claim 7, wherein said masking layer is applied by electro-photography and lithographic or offset printing

11. The method of claim 7, further comprising the step of plating said masked substrate.

12. A printed circuit board comprising:
a substrate;
a conductive polymer laced with a catalytic reducing agent coated on said substrate; and
a metal layer area partially covering said coated substrate.

13. The printed circuit board of claim 12, wherein said conductive polymer comprises a poly (3, 4-ethylenedioxythiophene)-poly (styrenesulfonate).

14. The printed circuit board of claim 12, wherein said catalytic reducing agent comprises a nano-particle metal.

15. The printed circuit board of claim 14, wherein said nano-particle metal comprises palladium.

16. The printed circuit board of claim 12, wherein said substrate is made of paper or plastic.

17. The printed circuit board of claim 12, further comprising a masking layer between said coated substrate and said metal layer.

18. The printed circuit board of claim 12, wherein said metal layer comprises copper or nickel.

19. The printed circuit board claimed in claim 12, wherein conductive polymer further contains wetting agents and/or cross-linking agents.

20. The printed circuit board claimed in claim 12, wherein conductive polymer further contains fine particle colloidal silver or other metals.

21. A method of making a printed circuit board comprising the steps of:
coating a surface of a first substrate with a polymer laced with a catalytic reducing agent;
forming a plurality of layers on said first substrate; and
connecting said plurality of layers by printing conductive vias between said layers.

22. The method of claim 21, wherein the steps of forming each layer comprises applying a masking layer to the coated surface of said substrate, and plating said masked substrate.

23. A printed circuit board comprising:
a substrate;
a conductive polymer laced with a catalytic reducing agent coated on said substrate;
a plurality of layers formed on said first substrate; and
printed conductive vias connecting said plurality of layers.

24. A method of making a printed circuit board comprising the steps of:
combining a conductive polymer with ink for a printer;
printing a circuit on a substrate;
curing or setting the ink containing the polymer on said substrate, wherein said polymer is laced with a catalytic reducing agent.

25. The method of claim 21, wherein said polymer comprises a poly (3, 4-ethylenedioxythiophene)-poly (styrenesulfonate).

26. The method of claim 24, wherein the catalytic reducing agent comprises a nano-particle metal.

27. The method of claim 26, wherein said nano-particle metal comprises palladium.

28. The method of claim 24, wherein said polymer also contains wetting agents and/or cross-linking agents.

29. The method of claim 24, wherein said polymer also contains fine particle colloidal silver or other metals.

30. The method of claim 24, further comprising the step of applying the ink with its component parts on the surface of said substrate forming a moderately conductive circuit.

31. The method of claim 30, wherein said circuit is applied using electro-photography with a conductive toner or by direct printing with a conducting lithographic ink, lacquer or varnish.

32. The method of claim 30, wherein said circuit layer is applied by ink-jet printing directly on the surface of said substrate.

33. The method of claim 30, wherein said circuit layer is applied by electro-photography and lithographic or offset printing.

34. The method of claim 30, further comprising the step of plating said masked substrate.

35. A printed circuit board comprising:
a substrate;
a conductive polymer laced with a catalytic reducing agent printed on said substrate; forming a mildly conductive circuit;
a metal layer area partially covering said coated substrate.

36. The printed circuit board of claim 35, wherein said conductive polymer comprises a poly (3, 4-ethylenedioxythiophene)-poly (styrenesulfonate).

37. The printed circuit board of claim 35, wherein said catalytic reducing agent comprises a nano-particle metal.

38. The printed circuit board of claim 35, wherein said nano-particle metal comprises palladium.

39. The printed circuit board of claim 35, wherein said substrate is made of paper or plastic.

40. The printed circuit board of claim 35, further comprising a masking layer between said coated substrate and said metal layer.

41. The printed circuit board of claim 35, wherein said metal layer comprises copper or nickel.

42. The printed circuit board claimed in claim 35 wherein conductive polymer further contains wetting agents and/or cross-linking agents.

43. The printed circuit board claimed in claim 35, wherein conductive polymer further contains fine particle colloidal silver or other metals.

44. A method of making a printed circuit board comprising the steps of:
printing on a surface of a first substrate with an ink containing a polymer laced with a catalytic reducing agent;
forming a plurality of layers on said first substrate by printing with an ink containing a laced polymer;
electroplating said plurality of layers;
printing a masking insulating layer;
connecting said plurality of layers by printing conductive vias between said layers.

45. The method of claim 25, wherein the steps of forming each layer comprises applying a masking layer to the coated surface of said substrate, and plating said masked substrate.

46. A printed circuit board comprising:
a substrate;
a conductive polymer laced with a catalytic reducing agent coated on said substrate;
a plurality of layers formed on said first substrate; and
printed conductive vias connecting said plurality of layers.
